(19) United States
(12) Patent Application Publication
(10) Pub. No.: US 2025/0237713 A1
(43) Pub. Date: Jul. 24, 2025

(54) BI-DIRECTIONAL FAULT MANAGED POWER

(71) Applicant: Cisco Technology, Inc., San Jose, CA (US)

(72) Inventors: George Allan Zimmerman, Manhattan Beach, CA (US); Chad M. Jones, Doylestown, OH (US); Jason Dewayne Potterf, Austin, TX (US); Joel Richard Goergen, Soulsbyville, CA (US); Elizabeth Kochuparambil, Morgan Hill, CA (US)

(21) Appl. No.: 18/417,661

(22) Filed: Jan. 19, 2024

(51) Int. Cl. G01R 31/58; G01R 31/52

(52) U.S. Cl. CPC G01R 31/58; G01R 31/52

(57) ABSTRACT

A power transceiver with bi-directional fault managed power is provided that enable role reversals and fault detections. Specifically, a method is provided in which a first power transceiver detects whether a fault is present on one or more wires. The first power transceiver is configured to transmit power over the one or more wires from a power source device to a second power transceiver. The method further includes determining whether the fault is an intentional fault generated by the second power transceiver and controlling the first power transceiver to switch to a receiver mode for receiving the power over the one or more wires from the second power transceiver based on determining that the fault is the intentional fault.

### TECHNICAL FIELD

The present disclosure relates to power distribution, data management, and data communications.

### BACKGROUND

The term Fault Managed Power (FMP) (also referred to as Extended Safe Power (ESP)) as used herein refers to power operation delivered on one or more wires or wire pairs. FMP may use pulse power or other types of power. That is, FMP may be accomplished in a non-pulsing manner. FMP may involve fault sensing with or without the use of pulse power. Power and data may be transmitted together (in-band) on at least one wire pair. FMP includes a fault detection (e.g., fault detection (safety testing) at initialization and between high voltage pulses), and pulse synchronization between a power sourcing equipment (PSE) and a powered device (PD). The power may be transmitted with communications or without communications.

### BRIEF DESCRIPTION OF THE DRAWINGS

FIG. 1 is a block diagram illustrating a power system in which bi-directional FMP is enabled, according to an example embodiment.

FIGS. 2A-2C illustrate timing diagrams for switching a power transceiver from a transmitter mode in which power is being transmitted to another power transceiver to a receiver mode in which power is being received from another power transceiver, according to various example embodiments.

FIG. 3 is a block diagram illustrating hardware components of a first power transceiver and a second power transceiver, configured to detect an intentional fault to switch between the transmitter mode and the receiver mode, according to an example embodiment.

FIG. 4 is a view illustrating a state diagram in which a power transceiver in a transmitter mode is switched to a receiver mode, according to an example embodiment.

FIG. 5 is a diagram illustrating power sources for generating an intentional fault by a receiver module of a power transceiver, according to one or more example embodiments.

FIG. 6 is a flow diagram illustrating a method in which a power transceiver in a receiver mode is switched to a transmitter mode, according to an example embodiment.

FIG. 7 is a flow diagram illustrating a fault managed power (FMP) communication method for reversing operating modes of a first and second power transceivers, according to an example embodiment.

FIG. 8 is a view illustrating a fault verification diagram in which a power fault verification is performed, according to an example embodiment.

FIGS. 9A and 9B are fault detection diagrams in which power pulses are being transmitted by a transmitter module of a power transceiver and one or more power faults are being detected in off pulse intervals, according to various example embodiments.

FIGS. 10A-10C are fault verification diagrams in which power pulses are being transmitted by a transmitter module of a power transceiver and one or more power faults are being detected based on one or more verification pulses in off pulse safety check intervals, according to various example embodiments.

FIG. 11 is a flowchart illustrating a method in which a first power transceiver is switching to a receiving mode based on an intentional fault, according to an example embodiment.

FIG. 12 is a flowchart illustrating a method in which a first power transceiver is switching to a receiving mode based on a power pulse, according to an example embodiment.

FIG. 13 is a flowchart illustrating a method in which a power fault may be detected during a power safety check interval, according to an example embodiment.

FIG. 14 is a hardware block diagram of a power transceiver that may perform functions associated with any combination of operations in connection with the techniques depicted and described in FIGS. 1-13, according to various example embodiments.

### DESCRIPTION OF EXAMPLE EMBODIMENTS

### Overview

Briefly, methods are presented for deploying one or more power transceivers with bi-directional fault managed power in which role reversals and fault detections are enabled.

In one form, a method is provided, which includes detecting, by a first power transceiver, whether a fault is present on one or more wires. The first power transceiver is configured to transmit power over the one or more wires from a power source device to a second power transceiver. The method further includes determining whether the fault is an intentional fault generated by the second power transceiver and controlling the first power transceiver to switch to a receiver mode for receiving the power over the one or more wires from the second power transceiver based on determining that the fault is the intentional fault.

In another form, a method is provided, which involves transmitting, by a first power transceiver, a power comprising a plurality of power pulses over one or more wires to a second power transceiver and detecting, by the first power transceiver, at least one pulse transmitted in an opposite direction from the plurality of power pulses. The method further involves switching, by the first power transceiver, from transmitting the power to receiving power based on detecting the at least one pulse in the opposite direction.

In yet another form, a method is provided, which includes initiating a power safety check interval between at least two power pulses transmitted by a first power transceiver over one or more wires to a second power transceiver. During the power safety check interval, the first power transceiver performs detecting a first fault based on a first predetermined voltage or a first predetermined current and transmitting a verification pulse over the one or more wires to the second power transceiver based on detecting the first fault. The method further involves, during the power safety check interval, detecting a second fault based on the verification pulse, where the second fault is based on a second predetermined voltage or a second predetermined current. The method further involves, during the power safety check interval, determining whether a power fault is present on the one or more wires based on detecting the second fault.

### EXAMPLE EMBODIMENTS

Techniques presented herein enable fault detections and role reversals for power transceivers in a system in which a power source device, also called a Power Sourcing Equipment (PSE) in Power over Ethernet (PoE) terminology, supplies power over a cable, such as an Ethernet data cable (or more generally a current loop), to a Powered Device (PD) in PoE terminology.

As described above, power and data may be transmitted together (in-band) on at least one wire pair (e.g., twisted wire pair). FMP also includes fault detection (e.g., fault detection (safety testing) at initialization and between high voltage pulses), and pulse synchronization between the power sourcing equipment (PSE) and the powered device (PD). The power may be transmitted with communications (e.g., bi-directional communications) or without communications.

The term “pulse power” (also referred to as “pulsed power”) as used herein refers to power that is delivered in a sequence of pulses (alternating low direct current voltage state and high direct current voltage state) in which the voltage varies between a very small voltage (e.g., close to 0V, 3V) during a pulse-off interval and a larger voltage (e.g., >12V, >24V) during a pulse-on interval. High voltage pulse power (e.g., >56 VDC, >60 VDC, >300 VDC, ˜108 VDC, ˜380 VDC) may be transmitted from power sourcing equipment (PSE) to a powered device (PD) for use in powering the powered device (PD). Pulse power transmission may be through cables, transmission lines, bus bars, backplanes, PCBs (Printed Circuit Boards), and power distribution systems, for example. It is to be understood that the power and voltage levels described herein are only examples and other levels may be used. In another example embodiment of FMP, the voltage stays constant and the current is pulsed to a lower state at regular intervals. This allows for a constant voltage from the transmitting source(s), and can be a more efficient implementation.

As noted above, safety testing (fault sensing) may be performed through a low voltage safety check between high voltage pulses in the pulse power system, or a low current safety check between the higher current pulses in the pulse power system. Fault sensing may include, for example, line-to-line fault detection with low voltage sensing of the cable or components and line-to-ground fault detection with midpoint grounding. The time between high voltage pulses or high current pulses may be used, for example, for line-to-line resistance testing for faults and the pulse width may be proportional to DC (Direct Current) line-to-line voltage to provide touch-safe fault protection. The testing (fault detection, fault protection, fault sensing, touch-safe protection) may comprise auto-negotiation between power components. The high voltage DC pulse power may be used with a pulse-to-pulse decision for touch-safe line-to-line fault interrogation between pulses for personal safety.

FMP may be converted into Power over Ethernet (PoE) and used to power electrical components such as a network device, user equipment, an electric charging station, etc. In one or more example embodiments, power may be supplied using Single Pair Ethernet (SPE) and may include data communications (e.g., 1-10GE (Gigabit Ethernet)). The power system may be configured for PoE (e.g., conventional PoE or PoE+ at a power level <100 watts (W), at a voltage level <57 volts (V), according to IEEE 802.3af, IEEE 802.3at, or IEEE 802.3bt), Power over Fiber (PoF), advanced power over data, FMP, or any other power over communications system in accordance with current or future standards, which may be used to pass electrical power along with data to allow a single cable to provide both data connectivity and electrical power to components (e.g., battery charging components, server data components, electric vehicle components).

A power distribution system may provide FMP in a single pair or multi-pair system, while providing safety features. For example, the use of FMP (power and data with safety features) for all power systems from or to the battery or utility power provides for safe interaction when emergency personnel are responding to an incident. Additionally, according to one or more example embodiments, the power distribution system enables bi-directional FMP in which transceivers may switch between a receiving mode and transmitting mode based on an intentional fault generated by a power receiving module, based on a pulse power direction, and/or using FMP communication.

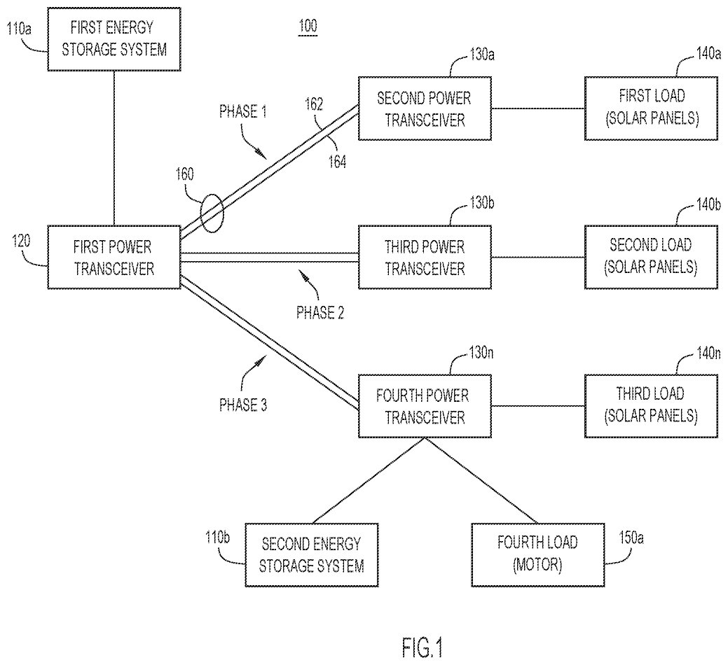

FIG. 1 is a block diagram illustrating a power distribution system 100 in which a bi-directional FMP is enabled, according to an example embodiment.

The power distribution system 100 includes multiple energy storage systems 110a-b such as a first energy storage system 110a and a second energy storage system 110b, multiple power transceivers such as a first power transceiver 120, a second power transceiver 130a, a third power transceiver 130b, and a fourth power transceiver 130n. The power distribution system 100 further includes multiple loads including a first load 140a (e.g., solar panels), a second load 140b, a third load 140n, and a fourth load 150a (e.g., a motor).

The notations 1, 2, 3 . . . n; a, b, c, . . . n; “a-n”, “a-d”, “a-f”, “a-g”, “a-k”, “a-c”, and the like illustrate that the number of elements can vary depending on a particular implementation and is not limited to the number of elements being depicted or described. Moreover, this is only examples of various components, and the number and types of components, functions, etc. may vary based on a particular deployment and use case scenario.

In one example embodiment, the power distribution system 100 is a multi-phase pulse power system in which pulse power is transmitted in multiple phases with pulses offset from one another between wires or wire pairs to provide continuous power. Using multi-phase pulse power may provide the power distribution system 100 less loss, with continuous uninterrupted power with overlapping phase pulses.

The first energy storage system 110a and the second energy storage system 110b powers various loads. Power received by the loads may be, for example, utility Alternating Current (AC) power, Direct Current (DC) power, FMP, and/or power from an alternative energy source such as a solar power system and/or a wind power system (e.g., 380 VDC or other voltage). The energy storage systems may include battery storage, a renewable energy source, a utility main power source, etc. The energy storage systems may have a power control and communications interface and a processor that is configured to determine available power. The processor may combine available power (utility power with renewable energy power and/or with battery power) and distribute or allocate the total available power among various FMP transceivers. In one example embodiment, the power from various energy storage systems and data may be combined and converted to Fault Managed Power (FMP) and transmitted to various user equipment or network devices (power loads or powered devices).

By way of an example, the first load 140a, the second load 140b, and the third load 140n may be solar panels or a solar array of window blinds that are powered by a renewable energy source e.g., the second energy storage system 110b, during nighttime. During daytime, the solar panels may source FMP power to the first energy storage system 110a. In other words, the loads 140a-n may be powered devices (PDs) during nighttime and may serve as a power sourcing equipment (PSE) during the daytime. For example, a first load 140a (solar panels) may provide power to the fourth load 150a (a motor) during daytime. To facilitate role reversals between the PSE and PDs, the power transceivers provide bi-directional FMP. In other words, the power transceivers are configured to switch between a power transmitting mode and a power receiving mode on the fly.

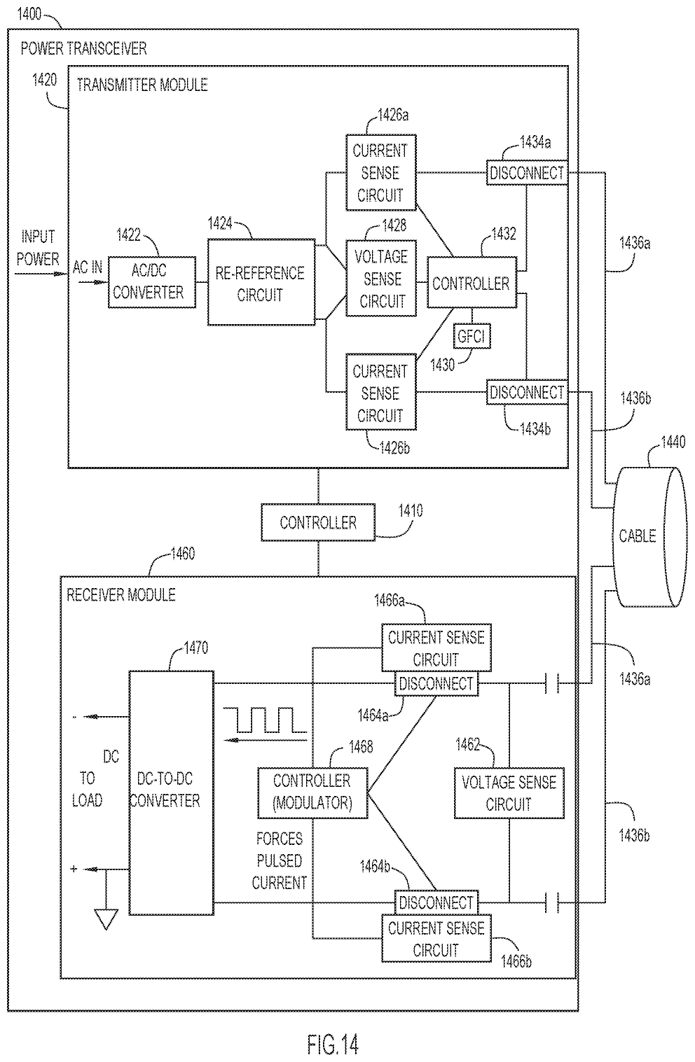

Each power transceiver includes an FMP transmitter module and an FMP receiver module such as in FIG. 14. By way of an example, the FMP transmitter module of the first power transceiver 120 provides power to the FMP receiver module of the second power transceiver 130a via a current loop 160 that includes a sending line 162 and a returning line 164. The current loop 160 may be contained within a cable i.e., twisted wire pair. In one example embodiment, the current loop 160 is at a phase 1. A similar current loop is provided between the first power transceiver 120 and the third power transceiver 130b and the fourth power transceiver 130n, respectively, but in different phases (at a phase 2 and at a phase 3, respectively).

The use of the term “current loop” here is not meant to be limiting. In some cases, a current loop could include a transmission line (line pair that includes two conductor: a send line and a return line) or it could refer to a configuration/environment in which a return path of the current loop is on a grounding conductor that is not one of the two lines of a line pair.

Power faults may occur in one or more of the current loops (e.g., the current loop 160) such as a line-to-ground fault, a line-to-line touch fault, a line-to-line short, a series arc fault, an overcurrent fault, a line-to-line arc fault, and/or a line-to-ground short. The power faults are detected by the FMP transmitter module of a respective power transceiver. An FMP receiver module of the second power transceiver 130a is configured to, on a periodic basis, disconnect from the current loop 160 to stop pulling power from current loop for a period of time to enable a safety check to be performed by the FMP transmitter module of the first power transceiver 120.

The FMP transmitter module monitors current on the current loop 160 to determine whether the current level on the current loop passes the safety check within a predetermined time interval. A determination that the current level was not within a safe range indicates a potential fault. The FMP transmitter module is configured to control connectivity of the power to the current loop 160 depending on whether the safety check has or has not passed within the predetermined time interval. Specifically, the FMP transmitter module is configured to determine whether the current level passes the safety check by determining whether the current level is less than a predetermined safety threshold corresponding to the safe range, and declaring the safety check passes when the current level is less than the predetermined safety threshold.

Additionally, the FMP transmitter module is configured to control mode of operations i.e., whether to switch the first power transceiver 120 from the transmitter mode to the receiver mode. For example, the FMP transmitter may determine that the current level during the safety check indicates that the fault is intentional i.e., generated by an FMP receiver module at the second power transceiver 130a. In which case, the first power transceiver 120 switches to receiving power from the second power transceiver 130a i.e., operates in the receiver mode.

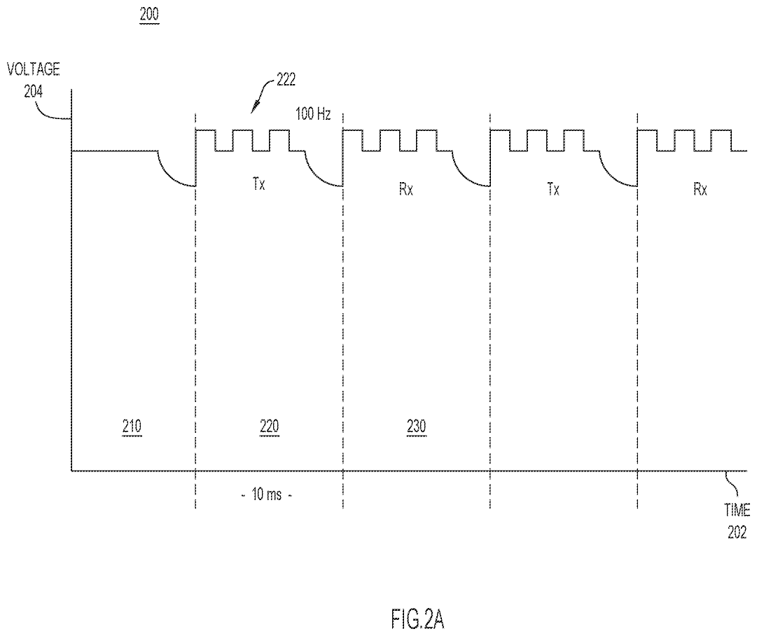

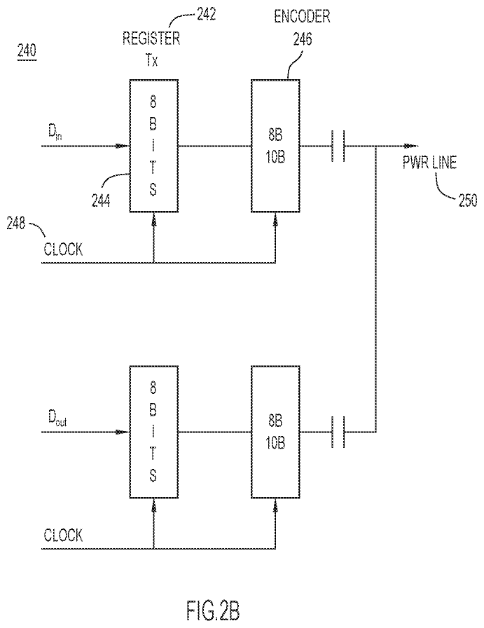

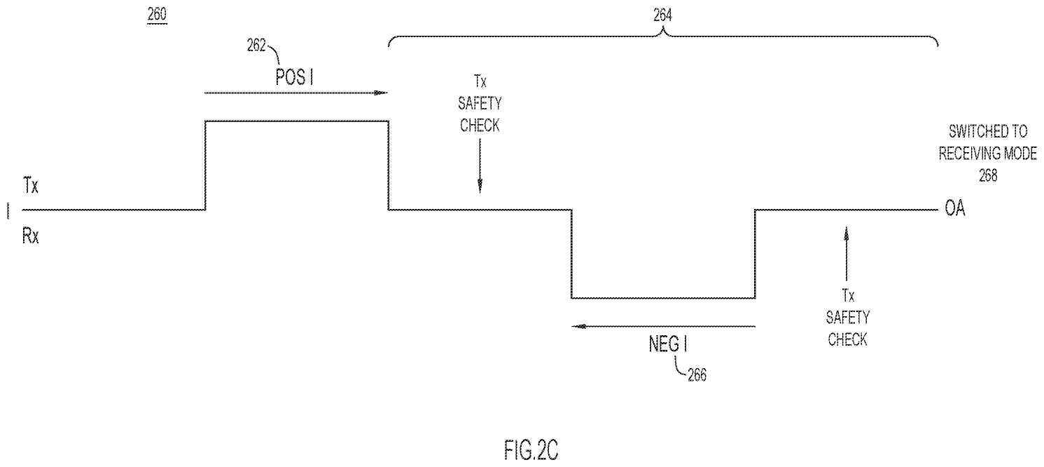

FIGS. 2A-2C illustrate timing diagrams for switching a power transceiver from a transmitter mode in which power is being transmitted to another power transceiver to a receiver mode in which power is being received from another power transceiver, according to various example embodiments.

In a first timing diagram 200 of FIG. 2A, time 202 is on the x-axis and voltage 204 is on the y-axis. The power transceiver is in the transmitter mode 210. A safety check interval 220 is then initiated, which may be approximately 10 milliseconds (ms) in duration. In the safety check interval 220, the voltage is varied by approximately 10V, shown as a sequence 222. The sequence 222 is detected by the power transceiver as an intentional fault to switch to the receiver mode 230. As such, the power transceiver is switching to the receiver mode 230.

In a second timing diagram 240 of FIG. 2B, using low frequency FMP power communications, the power transceiver may be switching between the transmitter mode and the receiver mode, according to an example embodiment. The second timing diagram 240 involves a transmitter register 242, an encoder 246, a clock 248, and a power line 250.

Specifically, the transmitter register 242 stores 8 bit data 244. The 8 bit data 244 is then encoded by the encoder 246 e.g., using 8B10B encoding. The encoded data is then transmitter from the FMP transmitter to the FMP receiver via the power line 250. The FMP receiver responds through the same 8 bit communications method, at which point, the FMP transmitter and the FMP receiver negotiate to switch modes. In the second timing diagram 240, the negotiations to switch roles is based on 8 bit messaging encoded with 8B10B and with the use of the clock 248. However, this is just one example, other bit lengths and other coding techniques may be deployed depending on a particular use case scenario.

In a third timing diagram 260 of FIG. 2C, current pulse direction is indicative of the mode. That is, current pulse direction is being used to switch the power transceiver between the receiver mode and the transmitter mode. Initially, the power transceiver is in a transmitter mode 262. In the transmitter mode 262, the power transceiver transmits a positive current (PosI) to another power transceiver. Next, a safety check interval 264 occurs in which the power transceiver detects a negative current 266 (NegI). The negative current 266 (NegI) indicates that the power transceiver is to switch to the receiver mode 268. The power line is then drained and the power transceiver is switched to the receiver mode 268 based on the negative current 266 (NegI) detected during the safety check interval 264.

The third timing diagram 260 is an example of the power transmitter switching between the transmitter mode and the receiver mode based on a pulse direction. If the current pulse direction changes, the power transceiver changes its operating mode from the transmitter mode to the receiver mode. The power transceiver in the transmitter mode controls role reversals. That is, while the request may be initiated at a power receiver, the power transmitter stops transmitting power to switch roles with the power receiver i.e., to change the operating mode with another power transceiver. The operating mode may be changed every other pulse based on the pulse direction. As such, this technique allows for a quick change between the transmitter mode and the receiver mode.

In one or more example embodiments, power transceivers include additional hardware components in the receiver module to generate an intentional fault i.e., to signal a change in the operating mode, which is then detected by the transmitter module of the other power transceiver.

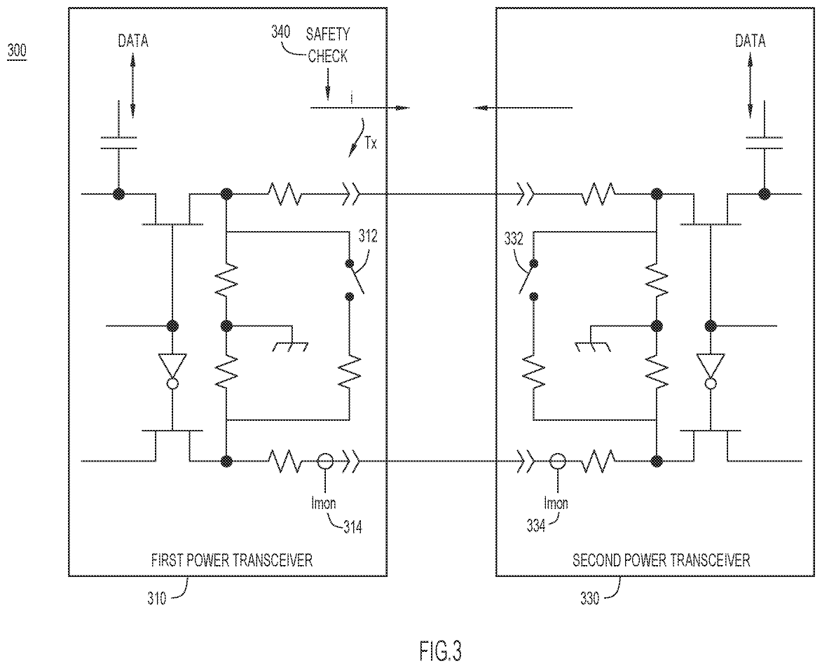

FIG. 3 is a block diagram illustrating hardware components 300 of a first power transceiver 310 and a second power transceiver 330 configured to detect an intentional fault to switch between the transmitter mode and the receiver mode, according to an example embodiment. The first power transceiver 310 includes a switch 312 and a resistor 314 and the second power transceiver 330 includes a switch 332 and a resistor 334.

When the second power transceiver 330 operates in the receiving mode, the switch 332 and the resistor 334 may generate an intentional fault during the safety check 340 to signal change of modes. The resistor 334 generates a unique or a distinct current I (or a voltage V in a voltage mode) that is unique to switching the operating mode. The first power transceiver 310 detects the unique or distinct current I and initiates the switch. For example, the first power transceiver 310 shuts down, drains the line, and switches to the receiver mode.

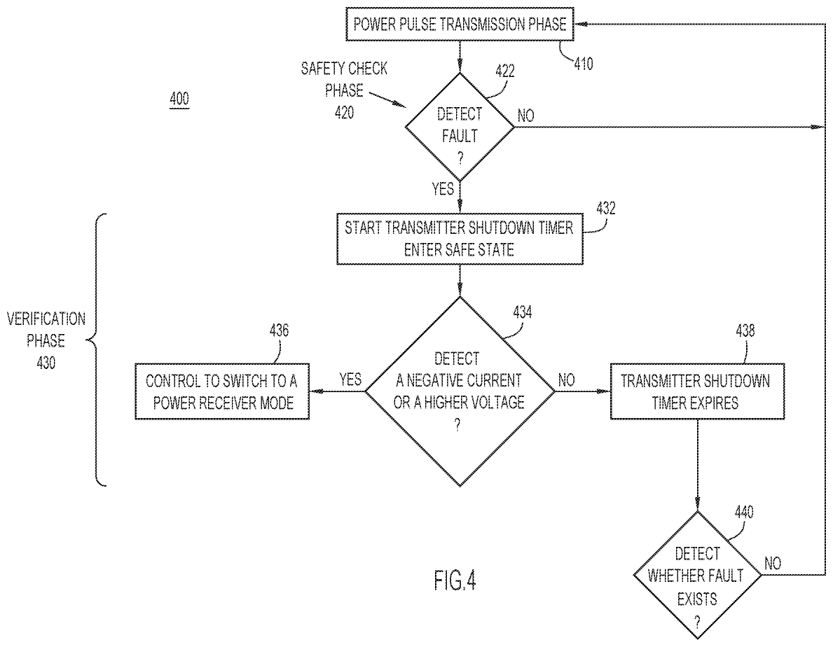

FIG. 4 is a view illustrating a state diagram 400 in which a power transceiver in a transmitter mode is switched to a receiver mode, according to an example embodiment. The state diagram 400 involves a power pulse transmission phase 410, a safety check phase 420, and a verification phase 430.

During the power pulse transmission phase 410, the power transceiver is configured to transmit one or more power pulses to another power transceiver. The power transceiver is operating in the transmitter mode and supplies power to another power transceiver. The receiver of the another power transceiver sinks the supplied power.

During the safety check phase 420, the power transceiver is configured to determine whether a power fault or an actual fault is detected and/or whether to switch to the receiver mode. Specifically, during the safety check phase 420, the power transceiver determines if a fault (voltage or current above a predetermined threshold value or outside an intended or expected value range) is detected, at 422. If the fault is not detected at 422, the power transceiver returns to the power pulse transmission phase 410 and continues to transmit power pulses to another power transceiver. On the other hand, if the fault is detected at 422, the power transceiver transitions to the verification phase 430.

In the verification phase 430, the power transceiver starts transmitter shutdown timer for a predetermined duration (e.g., 10 ms), at 432. The predetermined duration may vary based on user settings or system configurations. Once the shutdown timer is set, the power transceiver enters a safe state in which the line (e.g., the current loop 160 of FIG. 1) is being drained (no power pulses are being transmitted). In the safe state, the power transceiver stops transmitting power pulses (but may transmit verification pulses in some example embodiments, as discussed below).

In this safe state, the power transceiver checks whether voltage or current is indicate of an intentional fault. An intentional fault may be defined as a fake fault or fault that does not exist on the one or more wires. The intentional fault is defined as a fault generated by a receiver module of another power transceiver to switch the operating modes. The intentional fault is a special sequence or value outside a predetermined range that indicates that the operating mode should be switched. The intentional fault is a special trigger or a role reversal request. For example, at 434, the power transceiver determines whether a negative current or a voltage higher than a predetermined threshold voltage (or voltage range) is detected. Voltage that indicates an intentional fault is higher than any voltage value that would indicate an actual fault on the line or power wires.

If the intentional fault is detected, at 436, the power transceiver is switched from the transmitter mode to the receiver mode. The power transceiver is controlled to operate as a power receiver and stop transmitting the power pulses.

The verification phase 430 ends when the transmitter shutdown timer expires, at 438. At this time, the line should have been substantially drained and an actual fault check is performed at 440.

Specifically, at 440, the power transceiver detects whether a power fault exists on the line or wire. If the power fault is detected, the power transceiver may then determine if it is a ground fault, a line fault, a human fault (based on the power fault value(s)). In any event, the power transceiver then performs a power shutdown in which the power transceiver stops its operations and stops transmitting power pulses. If the power fault is not detected at 440, the power transceiver returns to the power pulse transmission phase 410 and continues to transmit power pulses.

Initiating or starting the transmitter shutdown timer in the verification phase 430 helps eliminate power surges and other insignificant power events. The timer may be set to various values e.g., 100 ms (when multiple verification checks) or 1-2 ms when only one verification check is performed. While this timer is on, the power transceiver is configured to detect voltage or current. In multiple verification checks, while the voltage is being detected, quick or shorter verification pulses are inserted. If a power fault is detected and/or verified, the power transceiver is shut down i.e., the line is drained to 0 volts and the power transceiver stops its operations (stops transmitting power pulses). If based on the verification pulse, low voltage or current is still incoming, this may define a special sequence indicative of a role reversal request i.e., the other power transceiver is trying to become a transmitter. As such, the power transceiver may be controlled to switch to the power receiver mode.

As noted above, in one or more example embodiments, the verification phase 430 may involve multiple quick verification checks in which verification pulses (small and shorter pulses) are generated and transmitted onto the line or wires. Using these small and/or shorter pulses, the power transceiver may determine whether it is an actual power fault and/or a type of power fault. These verification pulses may define a special sequence that indicates a request for role reversal (switch operating mode). These verification pulses may help eliminate shutdowns for power surges or other insignificant power events (false alarms). These verification pulses may define other special sequences to communicate special operating states or events, etc.

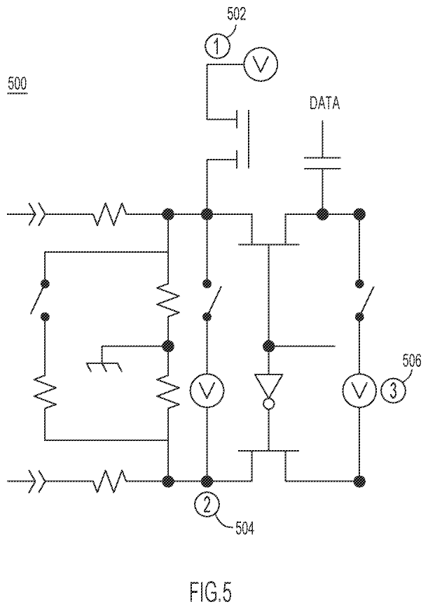

FIG. 5 is a diagram illustrating power sources 500 for generating an intentional fault by a receiver module of a power transceiver, according to one or more example embodiments. The power sources 500 may involve a field effect transistor (FET 502), a first switch 504, and a second switch 506.

The components of the receiver module that are configured to sink power pulses are also configured to switch to generating pulses for an intentional fault using the FET 502, the first switch 504 and/or the second switch 506. For example, if the FET 502 is open on the left side and is the only source of energy, the line would be 0 volts or eventually decay to 0 volts because resistors bleed it out. On the other hand, if it does not decay to 0 volts, this means that the FET 502 is closed on the right side and the power (voltage) is supplied to the line. The receiver module thus generates the intentional fault to trigger a change in the operating mode (a role reversal). This is just one non-limiting example.

In another example embodiment, by driving the first switch 504 and/or the second switch 506, power is supplied on the line, thus generating the intentional fault. A controller (not shown) may control the FET 502, the first switch 504, and/or the second switch 506 to serve as an energy source for generating the intentional fault.

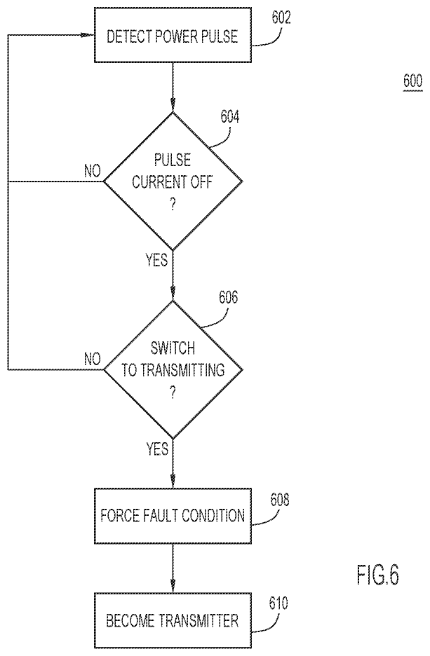

FIG. 6 is a flow diagram illustrating a method 600 in which a power transceiver in a receiver mode is switched to a transmitter mode, according to an example embodiment. The method 600 is performed by a receiver module of the power transceiver such as in FIG. 14.

The method 600 involves at 602, the receiver module detects power pulses transmitted by a transmitter module of another power transceiver. The receiver module may supply these power pulses to one or more loads to power the PDs e.g., solar blinds, motors, network devices, etc.

The method 600 further involves at 604, the receiver module determines whether the power pulse is off (current or voltage is stopped). This is a time period between power pulses, which may define a safety check interval initiated at the transmitter module of another power transceiver. If no (pulses are still detected), the receiver module returns to 602 to receive the power pulses and supply power to the PDs.

On the other hand, if the pulse current is off (yes at 604), the method 600 proceeds to determine if role reversal is to be initiated. Specifically, at 606, the receiver module determines if a switch in operating mode is intended (switch to transmitter mode). If at 606, the receiver module determines that switch is not intended, the receiver module returns to 602 to continue to receive power pulses and power the loads. If, at 606, the receiver module determines that role reversal is intended (e.g., based on an instruction from a controller), then at 608, the receiver module generates a force fault condition i.e., the intentional fault, using one or more of the energy sources in FIG. 5. The intentional fault may involve a substantially higher voltage than an actual power fault (outside an expected range), a negative current, and/or a special sequence of small power pulses that define a role reversal request.

Based on the force fault condition at 608, the power transceiver is switched to operating in the transmitter mode, at 610. The power transceiver starts transmitting power pulses to the other power transceiver using the transmitter module.

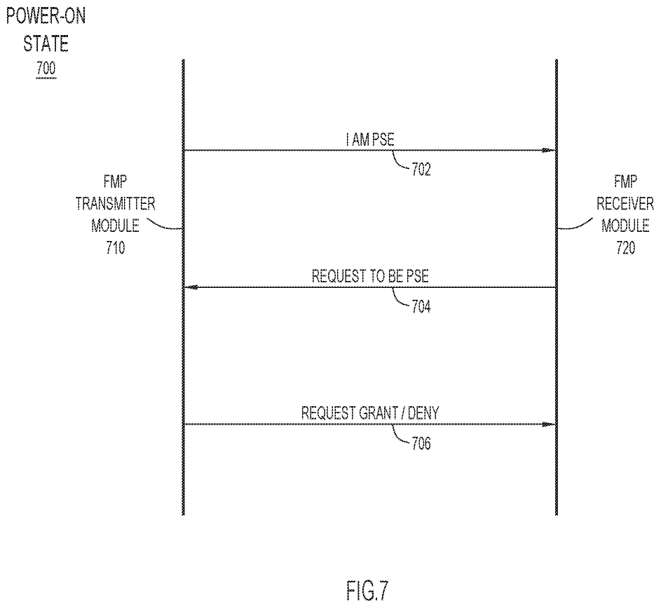

FIG. 7 is a flow diagram illustrating an FMP communication method 700 for reversing operating modes of a first and second power transceivers, according to an example embodiment. The FMP communication method 700 involves an FMP transmitter module 710 of a first power transceiver and a receiver module 720 of a second power transceiver.

In the FMP communication method 700, at 702, the FMP transmitter module 710 transmits an operating status message to the receiver module 720. The operation status message indicates that the FMP transmitter module 710 is the transmitter i.e., supplies power pulses (PSE). At 704, the receiver module 720 initiates a request to be the PSE. In other words, the receiver module 720 generates a request to switch the operating mode with the FMP transmitter module 710. At 706, the FMP transmitter module 710 transmits a response indicating whether the request is granted or denied. If the request is granted, the first power transceiver switches to the receiver mode and the second power transceiver switches to the transmitter mode.

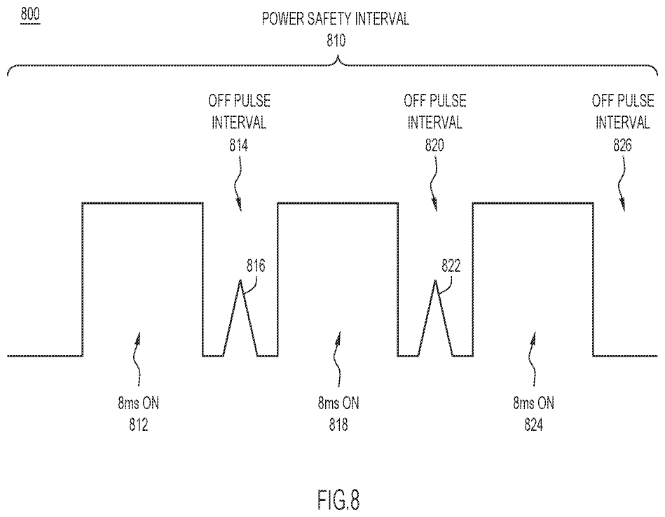

FIG. 8 is a view illustrating a fault verification diagram 800 in which a power fault verification is performed, according to an example embodiment. The fault verification diagram 800 illustrates a fault verification process in which false faults are eliminated or ignored. For example, power surges and other false positives are detected by an FMP transmitter module and are ignored to prevent unnecessary power shutdowns.

The fault verification diagram 800 shows a power safety check interval 810 in which the FMP transmitter module does not transmit power pulses onto one or more wires and instead performs a power safety check in which only verification pulses shorter and weaker than power pulses may be transmitted onto the one or more wires.

During the power safety check interval 810, the FMP transmitter module transmits a first short verification pulse 812 (not a power pulse that is intended to power a PD device). The first short verification pulse 812 may be a first predetermined voltage lower than the power pulse that powers a load and shorter in duration e.g., 8 ms.

At the off pulse interval 814, the FMP transmitter module is configured to detect a first fault 816 based on a first predetermined voltage or a first predetermined current. That is, if a fault is present on the line, the detected voltage or current (the first fault 816) would be higher than a predetermined threshold value anticipated from the first short verification pulse 812.

However, the first fault 816 being detected by the FMP transmitter module may also be indicative of a power surge or a false positive. Accordingly, the FMP transmitter module generates a second verification pulse 818. The FMP transmitter module transmits the second verification pulse 818 over the one or more wires to the FMP receiver module of another power transceiver based on detecting the first fault 816. For example, the second verification pulse 818 may be of another predetermined voltage value and another duration e.g., 4 ms (a second predetermined voltage or current).

At another off pulse interval 820, the FMP transmitter module is configured to detect a second fault 822 based on a second predetermined voltage or a second predetermined current. If a fault is present on the line, the detected voltage or current (the second fault 822) would be higher than the second predetermine threshold value i.e., voltage anticipated based on the second verification pulse 818. Similarly, the FMP transmitter module may generate and transmit a third verification pulse 824 and detect a fault during off pulse interval 826.

The number and type of verification pulses and detections may vary based on a particular configuration of a power transceiver and use case scenario. In each off pulse interval, the FMP transmitter module is configured to detect a fault. For example, based on detecting the first fault 816 and the second fault 822, the FMP power transmitter module is configured to determining whether a power fault is present on the one or more wires. When the power fault is detected, the FMP power transmitter module may be configured to stop transmitting power to another power transceiver.

Additionally, based on the first fault 816 and second fault 822, the FMP power transmitter may be configured to determine a fault type. The fault type may be one or more of: a line-to-ground fault, a line-to-line touch fault, a line-to-line short fault, an arc fault, an overcurrent fault, or a line-to-ground short fault.

When the power fault is not detected, the FMP power transmitter is configured to continue transmitting power pulses to another power transceiver over the one or more wires. Based on the power fault verification process, unnecessary shutdowns or false tripping may be avoided and the power distribution system functions reliably and safely. Additionally, the verification pulses may define a special sequence indicative of a particular condition or event such as but not limited a trigger signal to reverse operating modes (switching from the transmitter mode to the receiver mode).

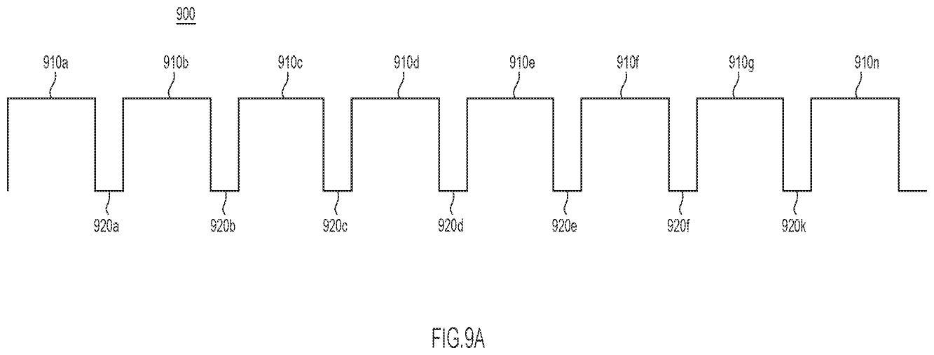

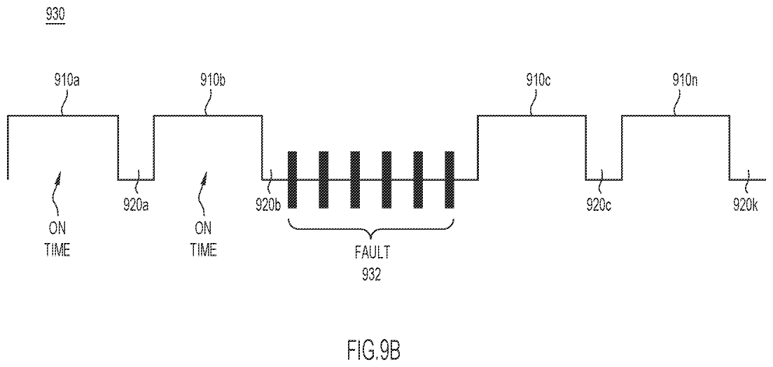

FIGS. 9A and 9B are fault detection diagrams in which power pulses are being transmitted by a transmitter module of a power transceiver and one or more power faults are being detected in off pulse intervals, according to various example embodiments. The transmitter module transmits power pulses 910a-n and performs safety checks during off pulse intervals 920a-k between the power pulses 910a-n. For example, the power pulses 910a-n include a first pulse 910a, a second pulse 910b, a third pulse 910c, a fourth pulse 910d, a fifth pulse 910e, a sixth pulse 910f, a seventh pulse 910g, and an eight pulse 910n. The off pulse intervals 920a-k may include a first off pulse interval 920a, a second off pulse interval 920b, and a third off pulse interval 920c, a fourth off pulse interval 920d, a fifth off pulse interval 920e, a sixth off pulse interval 920f, and a seventh off pulse interval 920k.

In FIG. 9A, a first fault detection diagram 900 is indicative of the transmitter module continuously operating without faults and transmitting power pulses 910a-n to a receiver module of another power transceiver that supplies power to one or more loads (powered devices). The transmitter module operates in a voltage mode, in one example embodiment. In yet another example embodiment, the transmitter module operates in a current mode, which is essentially the same as the voltage mode except that the current is being measured as opposed to the voltage, during the off pulse intervals 920a-k.

In FIG. 9B, a second fault detection diagram 930 is indicative of the transmitter module detecting a power fault 932 during the second off pulse interval 920b. That is, in the second off pulse interval 920b, voltage or current being detected indicates the power fault 932. If the power fault 932 is greater than a predetermined value (outside an expected range), the power fault 932 may be an intentional fault generated by the receiver module of another power transceiver to reverse the operating modes. Based on determining that the power fault 932 is the intentional fault, a controller of the power transceiver may switch the power transceiver to operate in the receiver mode.

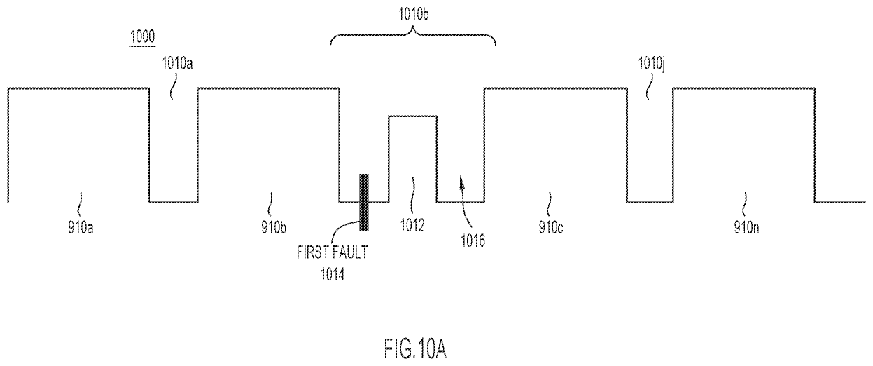

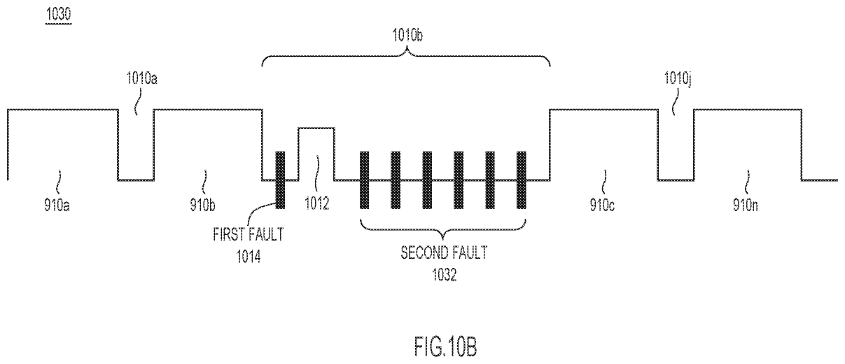

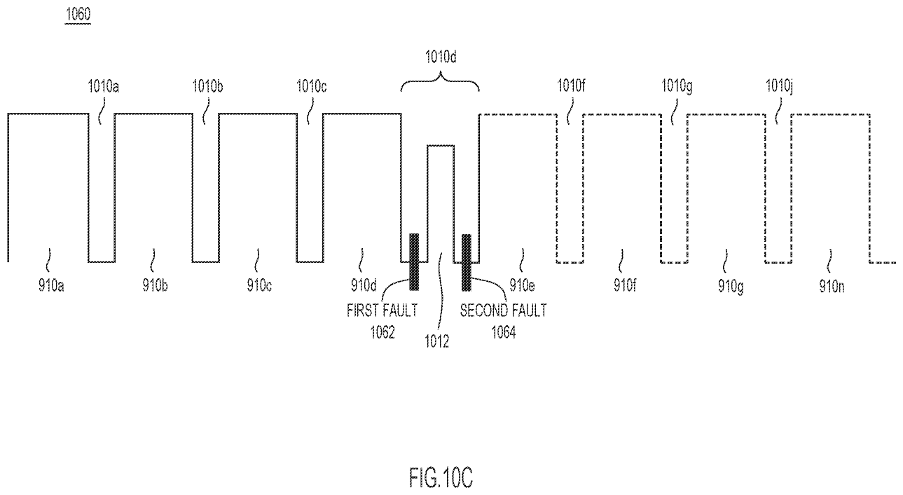

FIGS. 10A-10C are fault verification diagrams in which power pulses are being transmitted by a transmitter module of a power transceiver and one or more power faults are being detected based on one or more verification pulses in off pulse safety check intervals, according to various example embodiments. The transmitter module transmits power pulses 910a-n and performs safety checks during off pulse intervals 1010a-j between the power pulses 910a-n. During the off pulse intervals 1010a-j such as a first off pulse interval 1010a, a second off pulse interval 1010b, and a third off pulse interval 1010c, a fourth off pulse interval 1010d, a fifth off pulse interval 1010f, a sixth off pulse interval 1010g, and a seventh off pulse interval 1010j, one or more verification pulses (such as a verification pulse 1012) may be generated to validate or verify that an actual power fault exists.

In FIG. 10A, a first fault verification diagram 1000 is indicative of the transmitter module continuously operating without faults and transmitting power pulses 910a-n to a receiver module of another power transceiver to power to one or more loads (powered devices).

The transmitter module operates in a voltage mode, in one example embodiment. In yet another example embodiment, the transmitter module may operate in a current mode, which is essentially the same as the voltage mode except that the current is being measured as opposed to the voltage during the off pulse intervals 1010a-j. Also, during the off pulse intervals 1010a-j, verification pulses such as the verification pulse 1012, are generated to confirm or validate whether the power fault is present on one or more wires. In one example embodiment, based on detecting a first fault 1014, the transmitter module is configured to generate the verification pulse 1012 to confirm the presence or existence of the power fault. In yet another example embodiment, the verification pulse 1012 is automatically generated during the off pulse intervals 1010a-j regardless of whether the first fault 1014 is detected.

After transmitting the verification pulse 1012, the transmitter module detects a second fault based on the verification pulse 1012. Since no second fault is detected at 1016, the transmitter module continues to transmit power pulses. Without the verification pulse 1012, the transmitter module would have performed a power shutdown based on the first fault 1014. Based on the verification pulse 1012, the transmitter module confirms that the power fault does not exist. Since no fault is detected at 1016, the first fault 1014 is a false positive e.g., a power surge. As such, the transmitter module continues to provide power pulses and false tripping is prevented.

In FIG. 10B, a second fault verification diagram 1030 is indicative of the transmitter module detecting a power fault during the second off pulse interval 1010b, according to an example embodiment. That is, in the second off pulse interval 1010b, voltage or current is detected that indicates presence of the power fault (e.g., the first fault 1014). Further, based on the verification pulse 1012, a second fault 1032 is detected. The second fault 1032 confirms that an actual power fault exists. Based on the second fault 1032, the power transceiver is shut down and stops transmitting power pulses.

In FIG. 10C, a third fault verification diagram 1060 is indicative of the transmitter module detecting an intentional fault during the fourth off pulse interval 1010d, according to an example embodiment. The intentional fault is to trigger a change in an operating mode of the power transceiver.

Specifically, in the fourth off pulse interval 1010d, voltage or current is detected that indicates a presence of the power fault. The transmitter module detects a first fault 1062 and generates the verification pulse 1012. Based on the verification pulse 1012, the transmitter module detects a second fault 1064. The first fault 1062 and second fault 1064 are intentional faults generated by a receiver module of another power transceiver to trigger a switch in operating modes i.e., to induce role reversal. For example, the first fault 1062 and the second fault 1064 may be higher voltage values than the ones indicative of a power fault (outside the expected value range). The first fault 1062 and the second fault 1064 may be different values from one another. The first fault 1062 and the second fault 1064 may be a special sequence that defines a role reversal request.

In one or more example embodiments, the transmitter module is configured to detect voltages and/or current. In one or more example embodiments, the verification pulse 1012 may include a plurality of verification pulses, which are shorter than the power pulses 910a-n. The plurality of verification pulses may also vary in strength and duration from one another.

While the sequence of the first fault 1062 and the second fault 1064 is indicative of a role reversal request, the disclosure is not limited thereto. The sequence of intentional faults may be used to convey other conditions or triggers to the transmitter module. By way of an example, if the first fault 1062 is the same the second fault 1064, this may indicate a fault in a receiver or a power fault, whereas if the first fault 1062 is not equal to second fault 1064, this may indicate a role reversal request. By way of another example, a role reversal request may involve multiple faults and the multiple faults may be of a particular value or different values. By way of yet another example, different fault values may indicate different fault types.

The techniques presented herein provide bi-directional fault managed power in which transceivers detect and verify power faults and perform role reversals using FMP. For example, a power transceiver may change from a transmitter mode to a receiver mode based on power pulse direction, FMP communication, or based on an intentional fault generated by the receiver of another power transceiver.

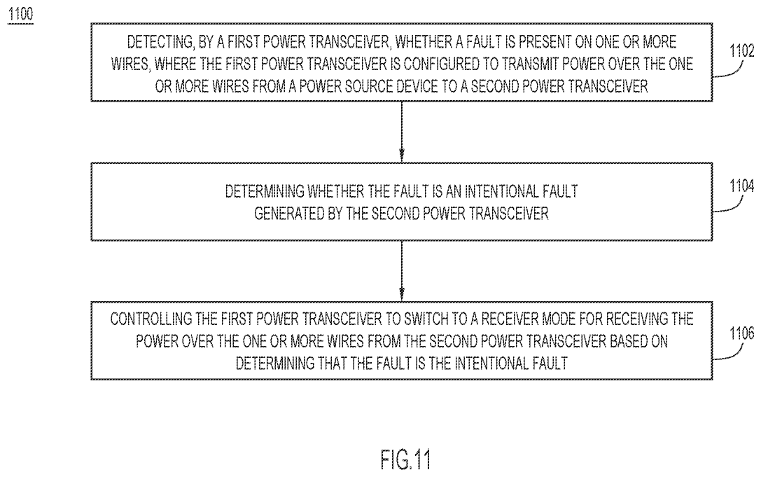

FIG. 11 is a flowchart illustrating a method 1100 in which a first power transceiver is switching to a receiving mode based on an intentional fault, according to an example embodiment.

The method 1100 involves, at 1102, detecting, by a first power transceiver, whether a fault is present on one or more wires. The first power transceiver is configured to transmit power over the one or more wires from a power source device to a second power transceiver.

The method 1100 further involves at 1104, determining whether the fault is an intentional fault generated by the second power transceiver.

The method 1100 further involves at 1106, controlling the first power transceiver to switch to a receiver mode for receiving the power over the one or more wires from the second power transceiver based on determining that the fault is the intentional fault.

In one form, in the method 1100, the power transmitted by the first power transceiver may be a fault managed power that includes a plurality of power pulses with a safety check interval between the plurality of power pulses for detecting the fault. In the method 1100, upon determining that the fault is the intentional fault, the first power transceiver receives the plurality of power pulses from the second power transceiver.

In one instance, the operation 1104 of determining whether the fault is the intentional fault may include first determining that a first fault is a first intentional fault received by the first power transceiver at a first safety check interval between first two power pulses and second determining that a second fault is a second intentional fault received by the first power transceiver at a second safety check interval between second two power pulses. The first intentional fault and the second intentional fault may be a special sequence to trigger the first power transceiver to switch from a transmitter mode to the receiver mode in which the power is received from the second power transceiver over the one or more wires.

In another instance, the operation 1102 of detecting whether the fault is present on the one or more wires may include detecting a current or a voltage outside a predetermined range during the safety check interval.

According to one or more example embodiments, the operation 1104 of determining whether the fault is the intentional fault may include detecting that the current is a negative current.

According to one or more example embodiments, the operation 1104 of determining whether the fault is the intentional fault may include determining that the fault is a higher voltage than a fault voltage that is indicative of the fault being present on the one or more wires.

In one form, the intentional fault may be generated using at least one resistor at the second power transceiver.

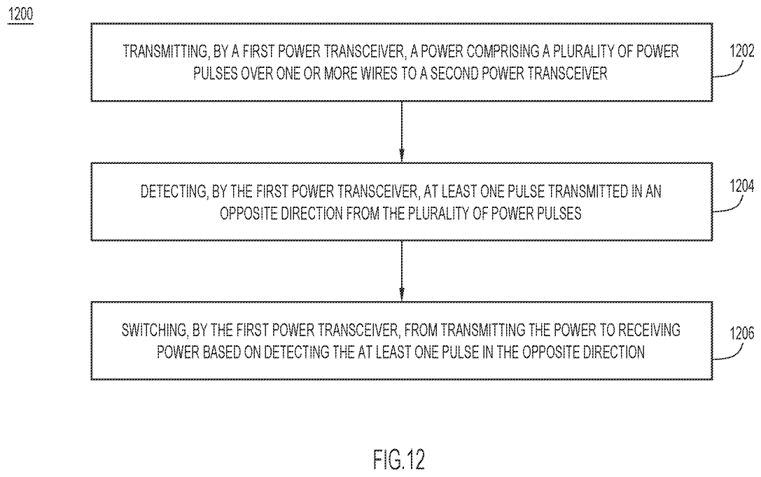

FIG. 12 is a flowchart illustrating a method 1200 in which a first power transceiver is switching to a receiving mode based on a power pulse, according to an example embodiment.

The method 1200 involves, at 1202, transmitting, by a first power transceiver, a power comprising a plurality of power pulses over one or more wires to a second power transceiver;

The method 1200 further involves at 1204, detecting, by the first power transceiver, at least one pulse transmitted in an opposite direction from the plurality of power pulses;

The method 1200 further involves at 1206, switching, by the first power transceiver, from transmitting the power to receiving power based on detecting the at least one pulse in the opposite direction.

In one form, the operation 1206 may include switching the first power transceiver between a transmitter mode in which the power is transmitted to the second power transceiver over the one or more wires and a receiver mode in which the power is received from the second power transceiver over the one or more wires.

According to one or more example embodiments, the at least one pulse in the opposite direction may be generated using at least one resistor at a power receiver from the first power transceiver or the second power transceiver.

In one instance, the at least one pulse in the opposite direction is generated using at least one resistor at a power receiver from the first power transceiver or the second power transceiver.

In another instance, the at least one pulse in the opposite direction may be generated at the second power transceiver by switching at least one component from sinking a current received via the one or more wires to generating the current that is being transmitted over the one or more wires to the first power transceiver.

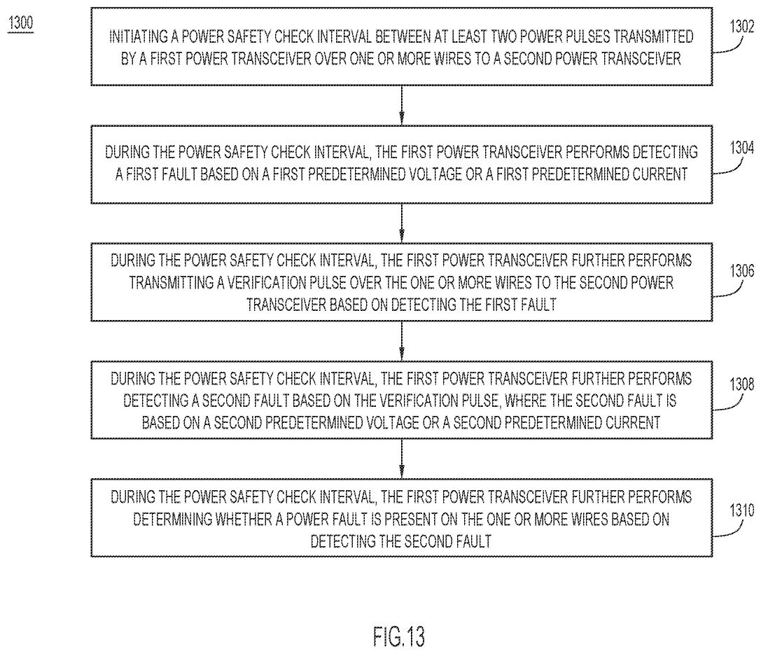

FIG. 13 is a flowchart illustrating a method 1300 in which a power fault may be detected during a power safety check interval, according to an example embodiment.

The method 1300 involves at 1302, initiating a power safety check interval between at least two power pulses transmitted by a first power transceiver over one or more wires to a second power transceiver.

The method 1300 further involves, during the power safety check interval, the first power transceiver performing, at 1304, detecting a first fault based on a first predetermined voltage or a first predetermined current and at 1306, transmitting a verification pulse over the one or more wires to the second power transceiver based on detecting the first fault.

The method 1300 further involves, during the power safety check interval, the first power transceiver performing, at 1308, detecting a second fault based on the verification pulse, wherein the second fault is based on a second predetermined voltage or a second predetermined current and at 1310, determining whether a power fault is present on the one or more wires based on detecting the second fault.

According to one or more example embodiments, the method 1300 may further include stopping the first power transceiver from transmitting power to the second power transceiver based on determining that the power fault is present on the one or more wires. The method 1300 may further include determining a fault type based on the first fault and the second fault. The fault type may be selected from among one or more of: a line-to-ground fault, a line-to-line touch fault, a line-to-line short fault, an arc fault, an overcurrent fault, or a line-to-ground short fault.

In one form, the method 1300 may further include continue transmitting power, by the first power transceiver to the second power transceiver over the one or more wires, based on determining that the power fault is not present on the one or more wires.

In one instance, the first predetermined current or the first predetermined voltage may be different from the second predetermined current or the second predetermined voltage.

In another instance, the verification pulse may be shorter in a duration than a power pulse.

In yet another instance, the power safety check interval may include a plurality of verification pulses based on which false wire faults are detected to continue transmitting power over the one or more wires.

In another form, the method 1300 may further involve, based on determining that the power fault is not present on the one or more wires, determining whether the first fault and the second fault are a role reversal request generated by the second power transceiver.

According to one or more example embodiments, the method 1300 may further involve controlling the first power transceiver to receiver power from the second power transceiver based on determining that the first fault and the second fault are the role reversal request.

In one instance, the first fault and the second fault that indicate the role reversal request may be the same predetermined voltage or the same predetermined current.

In another instance, the first fault may be a different voltage or a different current from the second fault, which define a special sequence for switching the first power transceiver between a power receiving mode and a power transmitting mode.

FIG. 14 is a hardware block diagram of a power transceiver 1400 that may perform functions associated with any combination of operations in connection with the techniques depicted and described in FIGS. 1-13, according to various example embodiments. The power transceiver 1400 includes a controller 1410, a transmitter module 1420 and a receiver module 1460.

The controller 1410 is configured to control the operations of the power transceiver 1400 including switching between a power receiving mode and a power transmitting mode, according to one or more example embodiments such as the ones described in FIGS. 1-13. The power transceiver 1400 is connected to lines 1436a and 1436b that may be contained within a cable 1440. The controller 1410 controls the transmitter module 1420 and the receiver module 1460 to connect and disconnect from the lines 1436a and 1436b within the cable 1440.

Specifically, the transmitter module 1420 may be a DC power transmitter that includes an AC/DC converter 1422, a re-reference circuit 1424, two current sense circuits (current sensors) 1426a and 1426b, a voltage sense circuit 1428 (voltage sensor), a ground fault circuit interrupter (GFCI) 1430, a controller (CTRL) 1432 and two disconnects 1434a and 1434b. The GFCI 1430 can operate any time (even when power is being delivered onto lines 1436a and 1436b) because it looks for mismatches as to what current is sent on one line and what current comes back on the other line. The current sense circuits 1426a and 1426b are associated with respective lines of a current loop, and are coupled to the disconnects 1434a and 1434b, respectively, which are in turn connected to lines 1436a and 1436b that may be contained within a cable 1440.

In the power transceiver 1400, power is input from a power supply source and may be in a form of AC power, DC power, and/or FMP power. In case, the AC power is input, the AC/DC converter 1422 converts the AC power producing a DC voltage (e.g., 380V DC). The re-reference circuit 1424 provides the DC voltage mid-point ground, producing two voltages at half of the DC voltage output by the AC/DC converter (e.g., +/−190V DC) onto two current paths. Each of these current paths traverses a current sensor, e.g., current sense circuits 1426a and 1426b, and their relative voltage is measured by the voltage sense circuit 1428. The controller 1432 receives the measurements from the current sense circuits 1426a and 1426b and the voltage sense circuit 1428. The controller 1432 may also be responsive to the GFCI 1430 during power delivery time periods for added safety. The current sense circuits 1426a and 1426b measure current from the re-reference circuit 1424 and passes these values to the controller 1432. The current then flows to a disconnect 1434a onto line 1436a into the cable 1440 (to a power receiver of another transceiver) and comes back on the return current path on line 1436b into a disconnect 1434b.

The controller 1432 actuates at least one of the disconnects 1434a and 1434b to isolate power source current from the lines 1436a and 1436b (forming a current loop when connected at opposite ends to a receiver module of another power transceiver) in the event safety criteria is not met according to the evaluation by the controller 1432 of the line conditions (line-to-line fault, a line-to-ground fault as detected by the GFCI 1430, or other current or voltage conditions detected by the controller 1432). The disconnects 1434a and 1434b may be relays or switches, such as field effect transistor (FET) switches, and in some embodiments, back-to-back FETs. The controller 1432 may be a microprocessor, microcontroller or other digital logic device (with fixed or programmable digital logic gates) configured to perform the fault detection and alerting. In one example embodiment, the controller 1432 and the controller 1410 is one entity. That is, the controller 1410 is configured to control the disconnects 1434a and 1434b and shut at least one of them down (disconnecting from at least one of the lines 1436a and 1436b) if the receiver module of another power transceiver (on the other end of the lines 1436a and 1436b) fails to do its safety check on the correct recurring basis, as described above. The controller 1432 will also trigger at least one of disconnects 1434a and 1434b if a fault is detected (i.e., the receiver module of another transceiver did perform the safety check but the current did not fall below the prescribed value). The controller 1432 is looking for the power on the line to shut off (because the power transmitter is expecting the power receiver to disconnect/interrupt on a recurring basis). The controller 1432 may be looking for this to happen at least once during the maximum safety check interval. The controller 1432 monitors current on at least one of the lines 1436a and 1436b via the current sense circuits 1426a and 1426b, watching them simultaneously. When the controller 1432 determines that safety has been met, it resets a counter/timer corresponding to the maximum safety check interval.

The controller 1410 together with the controller 1432 (which may be one controller) controls connectivity of power to the current loop depending on whether the safety check has or has not passed within the predetermined time interval. In one form, this controlling of the connectivity of the power to the current loop may involve disconnecting the power to the current loop when it is determined that the safety check has not passed within the predetermined time interval. Further, based on detecting that the fault is an intentional fault generated at the receiver module 1460 of another transceiver, the controller 1410 switching the power transceiver 1400 to operate in a receiving mode i.e., disconnects the transmitter module 1420 and connects the receiver module 1460.

The receiver module 1460 may be configured to receive DC power by way of an example. The receiver module 1460 is coupled to the cable 1440 containing lines 1436a and 1436b and is controlled by the controller 1410. The receiver module 1460 includes a voltage sense circuit 1462, disconnects 1464a and 1464b that are connected to lines 1436a and 1436b, respectively, current sense circuits 1466a and 1466b connected to sense current on lines 1436a and 1436b, respectively, a controller 1468 (modulator) and a DC-to-DC converter 1470. The lines 1436a and 1436b form a current loop between a transmission module such as the transmitter module 1420 of another power transceiver and the receiver module 1460.

The receiver module 1460 receives the cable 1440 (lines 1436a and 1436b) as input, with an optional ground reference. The voltage sense circuit 1462 makes a voltage measurement on the incoming power for telemetry, loop resistance calculation, or any other reason. This current path then traverses disconnects 1464a and 1464b as well as current sense circuits 1466a and 1466b on the respective line to enforce current limits. The controller 1468 is configured to modulate at least one of the disconnects 1464a and 1464b by disconnecting the further power reception stages at an interval to force a known current draw (likely near zero, but not necessarily). This demonstrates to the other power transceiver that no faults are present on the lines 1436a and 1436b and the receiver module 1460 is up and running. This power may then be fed to DC-to-DC converter 1470 that renders DC power at a voltage, e.g., 380V DC, 48V DC, or a voltage according to any other appropriate power delivery scheme. The disconnects 1464a and 1464b may be FETs, relays, etc. The controller 1468 may be a microprocessor, microcontroller or other digital logic device (with fixed or programmable digital logic gates) configured to perform the fault detection and alerting techniques described herein. In one example embodiment, the controller 1468 is the controller 1410. In other words, the controller 1410 performs the functions of the controller 1468.

The controller 1468 and/or the controller 1410 are configured to drive the at least one of disconnects 1464a and 1464b to disconnect from at least one of the lines 1436a and 1436b, respectively, to demonstrate safety at the desired interval. The current sense circuits 1466a and 1466b may be employed to provide telemetry, and also to provide current measurement to the controller 1468 and/or the controller 1410 if the load pulls too much current, serving as a backup plan if there is a short-circuit, etc. The controller 1468 and/or the controller 1410 and at least one of the disconnects 1464a and 1464b operate to interrupt the connection to a current loop (comprised of the lines 1436a and 1436b) on a recurring basis for the safety check interval, and then turn back on (e.g., after a minimum period has been observed).

While DC-to-DC converter 1470 is shown in FIG. 14, this is just one example. In another example embodiment, AC power may be received and AC to DC converter may be provided instead. Also, in this case, a power factor correction circuit may be provided and the disconnects 1464a and 1464b may take the form of triode for alternating current (TRIAC) devices or silicon controlled rectifier (SCR) devices that are able to handle AC currents. The power factor correction circuit may be used to maintain power quality (reduce harmonics in the power waveform), and the AC-to-DC converter converts the AC power to DC power that is provided to a load. In this instance, the controller 1468 provides controls to at least one of the disconnects 1464a and 1464b to interrupt the AC power to allow for the safety check to be performed. In one form, the controller 1468 initiates the interrupt around flattened zero crossings of the AC power waveform, subject to the condition that the load isolation point is at a time when there is a non-zero voltage on the line. If the interrupt is not performed around the flattened zero crossings, then the disconnects 1464a and 1464b take the form of SCRs to open at any time during the AC waveform to enable the transmission module of another transceiver (a second transceiver) to make measurements on the lines 1436a and 1436b.

In the Underwriters Laboratory (UL) power safety standards, depending on the operating voltage, a device manufacturer may be required to interrupt power more often than the line frequency in order to meet the safety criteria. This is true for higher voltages, and it may be necessary to interrupt at the peak of the AC waveform, for example, to run a safety check. As such, the receiver module 1460 is configured to interrupt power at both the flattened zero crossings and around the waveform peaks, for certain safety applications. If the voltage of the waveform is lower, it may be possible to rely on running the safety checks only around the flattened zero crossings.

The power transceiver 1400 may perform functions associated with any combination of operations in connection with the techniques depicted in FIGS. 1-13, according to various example embodiments, including, but not limited to, operations of a first transceiver and a second transceiver (each having a receiver module and a transmission module). It should be appreciated that FIG. 14 provides only an illustration of one example embodiment and do not imply any limitations with regard to the environments in which different example embodiments may be implemented. Many modifications to the depicted environment may be made.

In one or more example embodiments, a load may be a computing device or a network device that includes one or more processor(s), one or more memory element(s), a storage, a bus, one or more network processor unit(s) interconnected with one or more network input/output (I/O) interface(s), one or more I/O interface(s), and control logic. In various embodiments, instructions associated with logic for the computing device can overlap in any manner and are not limited to the specific allocation of instructions and/or operations described herein.

In another example embodiment, an apparatus is provided. The apparatus may be a first power transceiver that includes a receiver module configured to receive power from a second power transceiver over one or more wires, a transmission module configured to transmit power, from a power source, over the one or more wires to the second power transceiver, and a controller. The controller is configured to perform detecting whether a fault is present on the one or more wires and determining whether the fault is an intentional fault generated by the second power transceiver. The controller is further configured to perform switching the apparatus to a receiver mode for receiving the power over the one or more wires from the second power transceiver based on determining that the fault is the intentional fault.

In yet another example embodiment, an apparatus is provided. The apparatus may be a first power transceiver that includes a receiver module configured to receive power from a second power transceiver over one or more wires, a transmission module configured to transmit power, from a power source, over the one or more wires to the second power transceiver, and a controller. The transmission module is configured to transmit a power comprising a plurality of power pulses over the one or more wires to the second power transceiver. The controller is configured to detect at least one pulse transmitted in an opposite direction from the plurality of power pulses and switch the apparatus from transmitting the power by the transmission module to receiving power by the receiver module based on detecting the at least one pulse in the opposite direction.

In yet another example embodiment, an apparatus is provided. The apparatus may be a first power transceiver that is configured to perform power safety check. The apparatus includes a receiver module configured to receive power from a second power transceiver over one or more wires, a transmission module configured to transmit power, from a power source, over the one or more wires to the second power transceiver, and a controller. The controller is configured to perform initiating a power safety check interval between at least two power pulses transmitted by the transmission module over the one or more wires to the second power transceiver. During the power safety check interval, the controller performs detecting a first fault based on a first predetermined voltage or a first predetermined current and controls the transmission module to transmit a verification pulse over the one or more wires to the second power transceiver based on detecting the first fault. During the power safety check interval, the controller further performs detecting a second fault based on the verification pulse. The second fault is based on a second predetermined voltage or a second predetermined current. During the power safety check interval, the controller further performs determining whether a power fault is present on the one or more wires based on detecting the second fault

In yet another example embodiment, a system is provided. The system includes a first transceiver and a second transceiver that have the components and are configured to perform various operations, described in FIGS. 1-14.

In various embodiments, entities as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, storage and/or memory elements(s) can store data, software, code, instructions (e.g., processor instructions), logic, parameters, combinations thereof, and/or the like used for operations described herein. This includes the storage and/or memory elements(s) being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™ mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein, the terms may be used in a generic sense to include packets, frames, segments, datagrams, and/or any other generic units that may be used to transmit communications in a network environment. Generally, the terms reference to a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A method comprising:
detecting, by a first power transceiver, whether a fault is present on one or more wires, wherein the first power transceiver is configured to transmit power over the one or more wires from a power source device to a second power transceiver;
determining whether the fault is an intentional fault generated by the second power transceiver; and
controlling the first power transceiver to switch to a receiver mode for receiving the power over the one or more wires from the second power transceiver based on determining that the fault is the intentional fault.

2. The method of claim 1, wherein the power transmitted by the first power transceiver is a fault managed power that includes a plurality of power pulses with a safety check interval between the plurality of power pulses for detecting the fault, and wherein upon determining that the fault is the intentional fault, the first power transceiver receives the plurality of power pulses from the second power transceiver.

3. The method of claim 2, wherein determining whether the fault is the intentional fault includes:
first determining that a first fault is a first intentional fault received by the first power transceiver at a first safety check interval between first two power pulses; and
second determining that a second fault is a second intentional fault received by the first power transceiver at a second safety check interval between second two power pulses,
wherein the first intentional fault and the second intentional fault is a special sequence to trigger the first power transceiver to switch from a transmitter mode to the receiver mode in which the power is received from the second power transceiver over the one or more wires.

4. The method of claim 2, wherein detecting whether the fault is present on the one or more wires includes:
detecting a current or a voltage outside a predetermined range during the safety check interval.

5. The method of claim 4, wherein determining whether the fault is the intentional fault includes:
detecting that the current is a negative current.

6. The method of claim 4, wherein determining whether the fault is the intentional fault includes:
determining that the fault is a higher voltage than a fault voltage that is indicative of the fault being present on the one or more wires.

7. The method of claim 4, wherein the intentional fault is generated using at least one resistor at the second power transceiver.

8. A method comprising:
transmitting, by a first power transceiver, a power comprising a plurality of power pulses over one or more wires to a second power transceiver;
detecting, by the first power transceiver, at least one pulse transmitted in an opposite direction from the plurality of power pulses; and
switching, by the first power transceiver, from transmitting the power to receiving power based on detecting the at least one pulse in the opposite direction.

9. The method of claim 8, wherein the switching comprises switching the first power transceiver between a transmitter mode in which the power is transmitted to the second power transceiver over the one or more wires and a receiver mode in which the power is received from the second power transceiver over the one or more wires.

10. The method of claim 8, wherein the at least one pulse in the opposite direction is generated using at least one resistor at a power receiver from the first power transceiver or the second power transceiver.

11. The method of claim 8, wherein the at least one pulse in the opposite direction is generated at the second power transceiver by switching at least one component from sinking a current received via the one or more wires to generating the current that is being transmitted over the one or more wires to the first power transceiver.

12. A method comprising:
initiating a power safety check interval between at least two power pulses transmitted by a first power transceiver over one or more wires to a second power transceiver, wherein during the power safety check interval, the first power transceiver performs:
detecting a first fault based on a first predetermined voltage or a first predetermined current;
transmitting a verification pulse over the one or more wires to the second power transceiver based on detecting the first fault;
detecting a second fault based on the verification pulse, wherein the second fault is based on a second predetermined voltage or a second predetermined current; and
determining whether a power fault is present on the one or more wires based on detecting the second fault.

13. The method of claim 12, further comprising:
stopping the first power transceiver from transmitting power to the second power transceiver based on determining that the power fault is present on the one or more wires; and
determining a fault type based on the first fault and the second fault, wherein the fault type is selected from among one or more of: a line-to-ground fault, a line-to-line touch fault, a line-to-line short fault, an arc fault, an overcurrent fault, or a line-to-ground short fault.

14. The method of claim 12, further comprising:
continue transmitting power, by the first power transceiver to the second power transceiver over the one or more wires, based on determining that the power fault is not present on the one or more wires.

15. The method of claim 12, wherein the first predetermined current or the first predetermined voltage is different from the second predetermined current or the second predetermined voltage.

16. The method of claim 12, wherein the verification pulse is shorter in a duration than a power pulse.

17. The method of claim 12, wherein the power safety check interval comprises a plurality of verification pulses based on which false wire faults are detected to continue transmitting power over the one or more wires.

18. The method of claim 12, further comprising:
based on determining that the power fault is not present on the one or more wires, determining whether the first fault and the second fault are a role reversal request generated by the second power transceiver.

19. The method of claim 18, further comprising:
controlling the first power transceiver to receiver power from the second power transceiver based on determining that the first fault and the second fault are the role reversal request.

20. The method of claim 18, wherein the first fault and the second fault that indicate the role reversal request are same predetermined voltage or same predetermined current.

21. The method of claim 18, wherein the first fault is a different voltage or a different current from the second fault, which define a special sequence for switching the first power transceiver between a power receiving mode and a power transmitting mode.
